(19) United States
(12) Patent Application Publication
(10) Pub. No.: US 2010/0155108 A1
(43) Pub. Date: Jun. 24, 2010

(54) Electroless nickel plating solution composition, flexible printed circuit board and manufacturing method thereof

(75) Inventors: Chul Min Lee, Yeongi-gun (KR); Sung Wook Chun, Incheon-si (KR); Dek Gin Yang, Cheongwon-gun (KR); Kyung Jin Heo, Jinhae-si (KR); Young Ho Lee, Busan-si (KR); Dong-Gi An, Gimhae-si (KR)

Correspondence Address: STAAS & HALSEY LLP, SUITE 700, 1201 NEW YORK AVENUE, N.W., WASHINGTON, DC, 20005, US

(73) Assignees: SAMSUNG ELECTRO-MECHANICS CO., LTD., Suwon (KR); YMT CO., LTD., Incheon-si (KR)

(21) Appl. No.: 12/457,002

(22) Filed: May 28, 2009

(30) Foreign Application Priority Data
Dec. 23, 2008 (KR) 10-2008-0132036

(51) Int. Cl. H05K 1/00; B05D 5/12; C09D 1/00; C08K 3/10

(52) U.S. Cl. 174/254; 427/99.5; 106/1.22; 106/1.13; 106/1.12; 524/435

(57) ABSTRACT

The present invention relates to an electroless nickel plating solution composition, a flexible printed circuit board and a manufacturing method thereof, and more particularly, to an electroless nickel plating solution composition, a flexible printed circuit board and a manufacturing method thereof capable of simultaneously satisfying plating characteristics respectively required for a pad unit and external connection units of the flexible printed circuit board by forming a nickel plating layer having a vertical growth structure with the electroless nickel plating solution composition including a water-soluble nickel compound, a reducing agent, a complexing agent and a vertical growth inducer.

### CROSS-REFERENCE TO RELATED APPLICATIONS

This application claims the benefit of Korean Patent Application No. 10-2008-0132036, filed on Dec. 23, 2008 in the Korean Intellectual Property Office, the disclosure of which is incorporated herein by reference.

### BACKGROUND OF THE INVENTION

1. Field of the Invention

The present invention relates to an electroless nickel plating solution composition, a flexible printed circuit board and a manufacturing method thereof, and more particularly, to an electroless nickel plating solution composition, a flexible printed circuit board and a manufacturing method thereof capable of simultaneously satisfying plating characteristics respectively required for a pad unit and external connection units of the flexible printed circuit board by forming a nickel plating layer having a vertical growth structure with a vertical growth inducer.

2. Description of the Related Art

A flexible printed circuit board includes a circuit pattern on a substrate, a pad unit for mounting an electronic component and external connection units for being electrically connected to an external device. Here, the external connection units may include a terminal unit and a connector. The terminal unit can be electrically connected to the external device such as a liquid crystal panel by ACF bonding. Further, the connector can be electrically connected to the device by an attaching and detaching method.

Generally, the circuit pattern, the pad unit and the external connection units can be made of copper material. The copper material can be easily oxidized when exposed to the outside. Therefore, in case of mounting an electronic component on the oxidized pad unit, reliability of an electronic product is deteriorated, and a contact failure can be caused by increasing contact resistance between the pad unit and the electronic component. As a surface treatment to prevent these problems, general electroless nickel-substituted gold plating is performed on the pad unit, and direct gold plating is additionally performed only on the external connection units.

Generally, the electroless nickel-substituted gold plating has been well known in the art. For example, Korean Patent Laid-open Publication No. 2000-53621 discloses a method of manufacturing a printed circuit board using a plating solution including one or more water-soluble gold compounds, one or more conductive salts, one or more reducing agents and water after forming an electroless nickel phase in a copper-exposed portion to be gold-plated with photo solder resist (PSR). Further, Korean Patent Laid-open Publication No. 2003-0080547 discloses a method of providing an alloy plating layer made of gold (Au) and sliver (Ag) by using a gold-silver alloy plating solution after electroless nickel plating. Further, Japanese Patent Laid-open Publication No. 7-7243 discloses an electroless gold plating method performing a substitution reaction as a main reaction after forming an amorphous first electroless nickel coating film in a copper portion to be gold-plated and forming a crystalline second electroless nickel coating film. In addition, improved techniques for forming a nickel-gold plating layer on a copper layer are disclosed in U.S. Pat. Nos. 5,235,139 and 6,733,823.

Like this, the reasons for performing the general electroless nickel-substituted gold plating on the pad unit and the direct gold plating on the external connection units are as follows.

In case of the pad unit for mounting a general device, a chip or the like, the general electroless nickel-substituted gold plating improves solderability, but in case of performing the electroless nickel-substituted gold plating on the external connection units, cracks are generated by embrittlement of electroless nickel. Particularly, in case that the external connection unit is the terminal unit, since the terminal unit is bent by 360° while the liquid crystal panel is mounted by the ACF bonding, there is a crack problem. Further, in case that the external connection unit is the connector, cracks can be generated by bending or indentation of a coupling portion when inserting the connector or after coupling the connector. Therefore, the direct gold plating without nickel is performed only on the external connection units to prevent cracks. Further, the reason why the direct gold plating is not applied to the pad unit is that reliable solderability can't be achieved due to a tombstone phenomenon, a microvoid due to surface diffusion of copper and reduction of a chip shear value when mounting an electronic component, in case of performing only the gold plating. Here, the tombstone phenomenon means a soldering failure that one end of a chip component is coupled in a state of not being soldered.

Like this, in manufacture of a printed circuit board, the pad unit on which a component is mounted is given with solderability by performing the above-described general electroless nickel-substituted gold plating, and the terminal unit requiring flexibility during the ACF bonding and the detachable connector part are given with flexibility and crack resistance by additionally forming a direct gold plating layer, thereby improving reliability of an electronic product and reducing a failure rate thereof.

However, since the different surface treatments, that is, a double plating process of the electroless nickel plating and the direct gold plating should be performed on the pad unit and the external connection units, there have been problems such as deterioration of economical efficiency and productivity due to a complicated manufacturing process of the flexible printed circuit board.

### SUMMARY OF THE INVENTION

The present invention has been proposed in order to solve the above-described problems, and it is, therefore, an object of the present invention to simultaneously satisfy characteristics respectively required for a pad unit and external connection units of a flexible printed circuit board by forming a nickel plating layer having a vertical growth structure with a vertical growth inducer.

In accordance with an aspect of the present invention to achieve the object, there is provided an electroless nickel plating solution composition including a water-soluble nickel compound, a reducing agent, a complexing agent and a vertical growth inducer.

Here, the vertical growth inducer may include a compound having bismuth ions.

Further, a composition range of the vertical growth inducer may be 0.001 to 1 wt % based on the total content of the electroless nickel plating solution composition.

Further, the electroless nickel plating solution composition may further include a vertical growth supplement. Here, the vertical growth supplement may include at least one or two or more selected from a group consisting of thallium ions, iron ions and copper ions.

Further, the water-soluble nickel compound may include at least one of nickel sulfate and nickel chloride.

Further, a composition range of the water-soluble nickel compound may be 1 to 10 wt % based on the total electroless nickel plating solution composition.

Further, the reducing agent may include at least one selected from a group consisting of hypophosphorous acid, potassium hypophosphite, hydrazine and sodium hypophosphite.

Further, a composition range of the reducing agent may be 1 to 10 wt % based on the total electroless nickel plating solution composition.

Further, the complexing agent may include at least one or two or more selected from a group consisting of lactic acid, glycolic acid and malic acid.

Further, a composition range of the complexing agent may be 1 to 10 wt % based on the total electroless nickel plating solution composition.

Further, the electroless nickel plating solution composition may include at least one among a sequestering agent, organic acid and alkali metal salt thereof, a monosaccharide, a surfactant and a stabilizer.

Here, the sequestering agent may include at least one or two or more selected from a group consisting of polycarboxylic acid derivatives, amino acetic acid derivatives and nitrilo-triacetic acid derivatives.

Further, a composition range of the sequestering agent may be 0.01 to 1 wt % based on the total electroless nickel plating solution composition.

Further, the organic acid and the alkali metal salt thereof may include at least one or two or more selected from a group consisting of acetic acid, sodium acetate, propionic acid, sodium propionate, formic acid, sodium formate, potassium formate, adipic acid, sodium adipate, succinic acid, sodium succinate and so on.

Further, a composition range of the organic acid and the alkali metal salt thereof may be 0.1 to 10 wt % based on the total electroless nickel plating solution composition.

Further, the monosaccharide may include at least one or two or more selected from a group consisting of glucose, fructose and galactose.

Further, a composition range of the monosaccharide may be 0.1 to 10 wt % based on the total electroless nickel plating solution composition.

Further, the surfactant may be a polyoxyethylene alkyl ether derivative.

Further, the surfactant may include at least one or two or more selected from a group consisting of polyoxyethylene lauryl ether, polyoxyethylene oleyl ether, polyoxyethylene cetyl ether, polyoxyethylene octyl ether, polyoxyethylene tridecyl ether, polyoxyethylene laurylamine ether and polyoxyethylene stearylamine ether.

Further, a composition range of the surfactant may be 0.01 to 10 wt % based on the total electroless nickel plating solution composition.

Further, the stabilizer may be a thio compound.

Further, the stabilizer may include at least one or two or more selected from a group consisting of thiourea, alkyl thiourea, a mercapto compound, a tyazole compound, sodium thiosulfate, sodium thiocyanate, potassium thiocyanate, thio glycolic acid and thio diglycolic acid.

Further, a composition range of the stabilizer may be 0.0001 to 0.1 wt % based on the total electroless nickel plating solution composition.

Further, a pH range of the electroless nickel plating solution composition may be 4 to 6.

In accordance with another aspect of the present invention to achieve the object, there is provided a flexible printed circuit board including a substrate having a circuit pattern formed thereon; a pad unit to mount an electronic component thereon while being electrically connected to the circuit pattern; external connection units electrically connected to an external device while being electrically connected to the circuit pattern; and a nickel plating layer having a vertical growth structure and formed on the pad unit with an electroless nickel plating solution composition including a water-soluble compound, a reducing agent, a complexing agent and a vertical growth inducer.

Here, the nickel plating layer is further formed on the external connection units.

Further, the external connection units may include at least one of a terminal unit and a connector unit.

Further, the nickel plating layer may include nickel having a composition range of 90 to 94 wt % and phosphorous having a composition range of 6 to 10 wt %.

Further, the nickel plating layer may have a thickness range of 1 to 5 μm.

Further, the flexible printed circuit board may further include a gold plating layer disposed on the nickel plating layer.

Further, the gold plating layer may have a thickness range of 0.05 to 1 μm.

Further, the electroless nickel plating solution composition may further include organic acid and alkali metal salt thereof, a stabilizer, a surfactant, a monosaccharide and a sequestering agent.

Further, the vertical growth inducer may include a compound having bismuth ions.

Further, the electroless nickel plating solution composition may further include a vertical growth supplement consisting of at least one or two or more selected from a group consisting of thallium ions, iron ions and copper ions.

Further, the flexible printed circuit board may further include an insulating layer disposed on the substrate while exposing the pad unit and the external connection units.

In accordance with still another aspect of the present invention to achieve the object, there is provided a manufacturing method of a flexible printed circuit board including the steps of preparing a substrate including a circuit pattern, a pad unit electrically connected to the circuit pattern and external connection units electrically connected to an external device while being electrically connected to the circuit pattern; and forming a nickel plating layer on the pad unit with an electroless nickel plating solution composition including a water-soluble nickel compound, a reducing agent, a complexing agent and a vertical growth inducer.

Here, the nickel plating layer may be further formed on the external connection units.

Further, a gold plating layer may be further formed on the nickel plating layer.

Further, in the step of forming the nickel plating layer, the electroless nickel plating solution composition may have a temperature range of 70 to 90° C.

Further, in the step of forming the nickel plating layer, a pH range of the electroless nickel plating solution composition may be 4 to 6.

Further, based on the total weight of the electroless nickel plating solution composition, a composition range of the water-soluble nickel compound may be 1.0 to 10.0 wt %, a composition range of the reducing agent may be 1.0 to 10.0 wt %, a composition range of the complexing agent may be 1.0 to 10.0 wt % and a composition range of the vertical growth inducer may be 0.001 to 1.0 wt %.

Further, the electroless nickel plating solution composition may further include 0.1 to 10.0 wt % of organic acid and alkali metal salt thereof, 0.0001 to 0.1 wt % of a stabilizer, 0.01 to 10.0 wt % of a surfactant, 0.1 to 10.0 wt % of a monosaccharide and 0.01 to 1.0 wt % of a sequestering agent, based on the total weight thereof.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a plan view of a flexible printed circuit board in accordance with a second embodiment of the present invention;

FIG. 2 is a cross-sectional view of the flexible printed circuit board illustrated in FIG. 1;

FIGS. 3 to 6 are cross-sectional views illustrating a manufacturing method of a flexible printed circuit board in accordance with a third embodiment of the present invention;

FIG. 7 is a photograph of a fracture cross-section of an electroless nickel plating layer having a vertical growth structure in accordance with an embodiment of the present invention; and

FIG. 8 is a photograph of a fracture cross-section of an electroless nickel plating layer having a vertical growth structure in accordance with a comparative example of the present invention.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, an electroless nickel plating solution composition in accordance with a first embodiment of the present invention will be described in detail, but the present invention is not limited thereto.

The electroless nickel plating solution composition in accordance with the first embodiment of the present invention may include a water-soluble nickel compound, a reducing agent, a complexing agent and a vertical growth inducer.

Here, the water-soluble nickel compound is a main material which is plated on a substrate by being precipitated. The water-soluble nickel compound may include at least one of nickel sulfate and nickel chloride. Specifically, for example, nickel sulfate salt (NiSO₄.6H₂O) may be used as the water-soluble nickel compound. A composition range of the water-soluble nickel compound may be 1.0 to 10.0 wt % based on the total weight of the electroless nickel plating solution composition. Preferably, the composition range of the water-soluble nickel compound may be 2.0 to 5.0 wt % based on the total weight of the electroless nickel plating solution composition. At this time, in case that a composition of the water-soluble nickel compound is less than 1.0 wt %, a plating speed is remarkably reduced and thus productivity can't be expected. On the other hand, in case that the composition of the water-soluble nickel compound is more than 10.0 wt %, since mixing ratios of the following complexing agent, reducing agent and so on should be correspondingly increased, there is a problem of increase in drag-out loss. Here, the drag-out loss means the amount of plating solution adhered to a plated product when the plated product goes out of a plating bath after finishing plating.

The reducing agent plays a role in reducing nickel ions to nickel metal. The reducing agent may include at least one selected from a group consisting of hypophosphorous acid, potassium hypophosphite, hydrazine and sodium hypophosphite. For example, sodium hypophosphite (NaH₂PO₂.6H₂O) may be used as the reducing agent. A composition range of the reducing agent may be 1.0 to 10 wt % based on the total weight of the electroless nickel plating solution composition. Preferably, the composition range of the reducing agent may be 1.5 to 3.0 wt % based on the total weight of the electroless nickel plating solution composition. At this time, in case that a composition of the reducing agent is less than 1.0 wt %, reducing power is reduced and thus the plating speed can be reduced. On the other hand, in case that the composition of the reducing agent is more than 10.0 wt %, a consumption rate of sodium hypophosphite according to consumption of nickel is exceeded and thus the drag-out loss can be increased.

The complexing agent plays a role in stably supplying nickel ions by complexing nickel salt. The complexing agent may include at least one or two or more selected from a group consisting of lactic acid, glycolic acid and malic acid. A composition range of the complexing agent may be 1.0 to 10.0 wt % based on the total weight of the electroless nickel plating solution composition. Preferably, the composition range of the complexing agent may be 2.0 to 5.0 wt % based on the total weight of the electroless nickel plating solution composition. At this time, in case that a composition of the complexing agent is less than 1.0 wt %, complexing power is reduced and thus it is difficult to uniformly supply the nickel ions. On the other hand, in case that the composition of the complexing agent is more than 10 wt %, the amount of nickel ions is exceeded. Thus, the drag-out loss is increased and the plating speed can be remarkably reduced.

The vertical growth inducer may be, for example, a compound having bismuth (Bi) ions. For example, bismuth sulfate, bismuth nitrate or the like may be used as the vertical growth inducer. Substantially, the bismuth ions play a role in changing orientation of crystal growth of nickel. That is, nickel can be grown to have a vertical structure with respect to a plated surface, by the bismuth ions.

A composition range of the vertical growth inducer may be 0.0001 to 1.0 wt % based on the total weight of the electroless nickel plating solution composition. Preferably, the composition range of the vertical growth inducer may be 0.001 to 0.1 wt % based on the total weight of the electroless nickel plating solution composition. At this time, in case that a composition of the vertical growth inducer is less than 0.0001 wt %, it can't contribute to vertical growth during nickel plating. On the other hand, the composition of the vertical growth inducer is more than 1.0 wt %, a skip can be generated during plating.

In addition, the electroless nickel plating solution composition may further include a vertical growth supplement capable of promoting the vertical growth of nickel. The vertical growth supplement may include at least one or two or more selected from thallium ions, iron ions and copper ions.

Hereinafter, a plating principle of the electroless nickel plating solution composition will be briefly described with reference to the following equations.

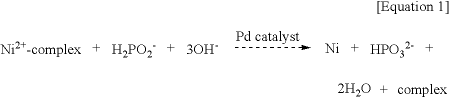

As shown in Equation 1, the water-soluble nickel compound makes the complexing agent and a complex. Meanwhile, dissociated hypophosphoric acid reduces nickel.

3H₂PO₂⁻+H⁺→HPO₃²⁻+2P+3H₂P [Equation 2]

As shown in Equation 2, phosphorous, which is eutectic with nickel, can be precipitated. Like this, reactions shown in Equations 1 and 2 can be consecutively generated.

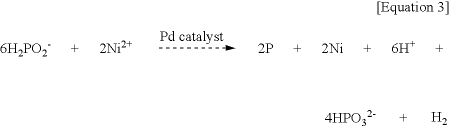

As shown in Equation 3, an alloy structure in which nickel is eutectic with phosphorous can be obtained.

Here, the electroless nickel plating solution composition further includes a sequestering agent to chelate palladium (Pd) or copper (Cu) ions mixed from the outside. That is, the sequestering agent plays a role in suppressing decomposition of the electroless nickel plating solution composition.

The sequestering agent may include at least one or two or more selected from a group consisting of polycarboxylic acid derivatives, amino acetic acid derivatives and nitrilo-triacetic acid derivatives. Specifically, for example, ethylene diamine tetra acetic acid, diethylene triamine penta-acetic acid, N-hydroxyethylethylene diamine triacetic acid, 1,3-diamino-2-propanol-N,N,N,N′-tetra acetic acid, bishydroxyphenyl-ethylene, diamine diacetic acid, N,N-di(hydroxyethyl)glycine or the like may be used as the sequestering agent. Here, the sequestering agent can be included in the electroless nickel plating solution composition by mixing one or two or more among the above materials.

A composition range of the sequestering agent may be 0.1 to 10.0 wt % based on the total weight of the electroless nickel plating solution composition. Preferably, the composition range of the sequestering agent may be 0.5 to 5.0 wt % based on the total weight of the electroless nickel plating solution composition. At this time, in case that a composition of the sequestering agent is less than 0.1 wt %, it is difficult to block the decomposition of the electroless nickel plating solution composition. On the other hand, in case that the composition of the sequestering agent is more than 10.0 wt %, since the electroless nickel plating solution has a predetermined lifetime, the amount of electroless nickel plating solution composition is excessively increased and thus the drag-out loss can be increased.

Further, the electroless nickel plating solution composition may further include at least one of organic acid and alkali metal salt thereof. The organic acid and the alkali metal salt thereof play a role in preventing reduction of a plating speed due to phosphorous acid (HPO₃²⁻) generated in Equation 2 and pH of the electroless nickel plating solution composition. That is, the organic acid and the alkali metal salt thereof can play roles of a plating speed accelerator and a pH buffer.

The organic acid and the alkali metal salt thereof may be a compound having at least one or more carboxyl. For example, acetic acid, sodium acetate, propionic acid, sodium propionate, formic acid, sodium formate, potassium formate, adipic acid, sodium adipate, succinic acid, sodium succinate or the like may be used as the organic acid and the alkali metal salt thereof. Here, the organic acid and the alkali metal salt thereof can be included in the electroless nickel plating solution by mixing one or two or more among the above materials.

A composition range of the organic acid and the alkali metal salt thereof is 0.1 to 10.0 wt % based on the total weight of the electroless nickel plating solution composition. Preferably, the composition range of the organic acid and the alkali metal salt thereof is 0.5 to 5.0 wt % based on the total weight of the electroless nickel plating solution composition. At this time, in case that a composition of the organic acid and the alkali metal salt thereof is less than 0.1 wt %, increase in the plating speed and a buffer effect may be weak. On the other hand, in case that the composition of the organic acid and the alkali metal salt thereof is more than 10 wt %, embrittlement of a plating layer is increased and thus flexibility can be remarkably reduced.

Further, the electroless nickel plating solution composition may further include a monosaccharide. Here, the monosaccharide plays a role in adjusting a phosphorus (P) content precipitated in Equation 2. Therefore, a sudden change of mechanical characteristics of the plating layer due to increase or reduction of phosphorus (P) is prevented. The monosaccharide may be at least one or more (CH₂O)ₙH, n=3˜6. Here, for example, glucose, fructose, galactose or the like may be used as the monosaccharide. Here, the monosaccharide can be included in the electroless nickel plating solution composition by mixing one or two or more among the above materials.

A composition range of the monosaccharide may be 0.1 to 10.0 wt % based on the total weight of the electroless nickel plating solution composition. Preferably, the composition range of the monosaccharide may be 0.5 to 5.0 wt % based on the total weight of the electroless nickel plating solution composition. At this time, in case that a composition of the monosaccharide is less than 0.1 wt %, phosphorus (P) is suddenly increased and thus flexibility can be reduced. On the other hand, in case that the composition of the monosaccharide is more than 10.0 wt %, the plating speed can be remarkably reduced.

Further, the electroless nickel plating solution composition may further include a surfactant. The surfactant plays a role in making a thickness deviation uniform according to a plated area and securing uniformity of grains. Further, the surfactant plays a role in improving flexibility by facilitating separation of hydrogen (H₂) gas. That is, the surfactant can play a role of a ductility improver of the plating layer.

The surfactant may be a polyoxyethylene alkyl ether derivative. For example, polyoxyethylene lauryl ether, polyoxyethylene oleyl ether, polyoxyethylene cetyl ether, polyoxyethylene octyl ether, polyoxyethylene tridecyl ether or the like, which is derived from R—O—(CH₂CH₂O)ₙH, may be used as the surfactant. Or, polyoxyethylene laurylamine ether, polyoxyethylene stearylamine ether or the like, which is derived from R—N—[(CH₂CH₂O)ₙH]₂, may be used as the surfactant. Here, the surfactant can be included in the electroless nickel plating solution composition by mixing one or two or more among the above materials.

A composition range of the surfactant may be 0.01 to 10.0 wt % based on the total weight of the electroless nickel plating solution composition. Preferably, the composition range of the surfactant may be 0.1 to 1.0 wt % based on the total weight of the electroless nickel plating solution composition. At this time, in case that a composition of the surfactant is less than 0.01 wt %, it is difficult to expect a ductility effect of the plating layer. On the other hand, the composition of the surfactant is more than 10.0 wt %, the plating speed is remarkably reduced and thus it is difficult to obtain the uniform plating layer.

Further, the electroless nickel plating solution composition may further include a stabilizer. Here, the stabilizer plays a role in blocking the decomposition of the plating solution. In addition, the stabilizer can play a role of a grain refiner to make precipitated nickel particles small. Here, in case that the grains become fine, solderability and flexibility can be improved. The stabilizer may be a thio compound having at least one or more —S—. For example, thiourea, alkyl thiourea, a mercapto compound, a tyazole compound, sodium thiosulfate, sodium thiocyanate, potassium thiocyanate, thio glycolic acid, thio diglycolic acid or the like may be used as the stabilizer. Here, the stabilizer can be included in the electroless nickel plating solution composition by mixing one or two or more among the above materials.

A composition range of the stabilizer may be 0.0001 to 0.1 wt % based on the total weight of the electroless nickel plating solution composition. Preferably, the composition range of the stabilizer may be 0.001 to 0.01 wt % based on the total weight of the electroless nickel plating solution composition. At this time, in case that a composition of the stabilizer is less than 0.0001 wt %, it is difficult to achieve stability of the plating solution and fineness of the grains. Further, in case that the composition of the stabilizer is more than 0.1 wt %, a skip can be generated since activation of the plating solution is delayed.

A pH range of the electroless plating solution composition may be 4 to 6 in consideration of the plating speed and reduction efficiency and stability.

Here, in case that additives such as the organic acid and the alkali metal salt thereof, the surfactant, the stabilizer and the monosaccharide are included in the electroless nickel plating solution composition, in addition to the vertical growth inducer, the most remarkable vertical-grown nickel plating layer can be obtained.

Hereinafter, a flexible printed circuit board using the above-described electroless nickel plating solution composition and a manufacturing method thereof will be described in detail with reference to the drawings. The following embodiments are provided to those skilled in the art, as examples, in order to sufficiently convey the spirit of the present invention. Therefore, the present invention is not limited to the following embodiments and may be embodied into other forms. And, in the drawings, sizes and thicknesses and the like of elements may be exaggeratingly expressed for convenience. Like reference numerals refer to like elements throughout.

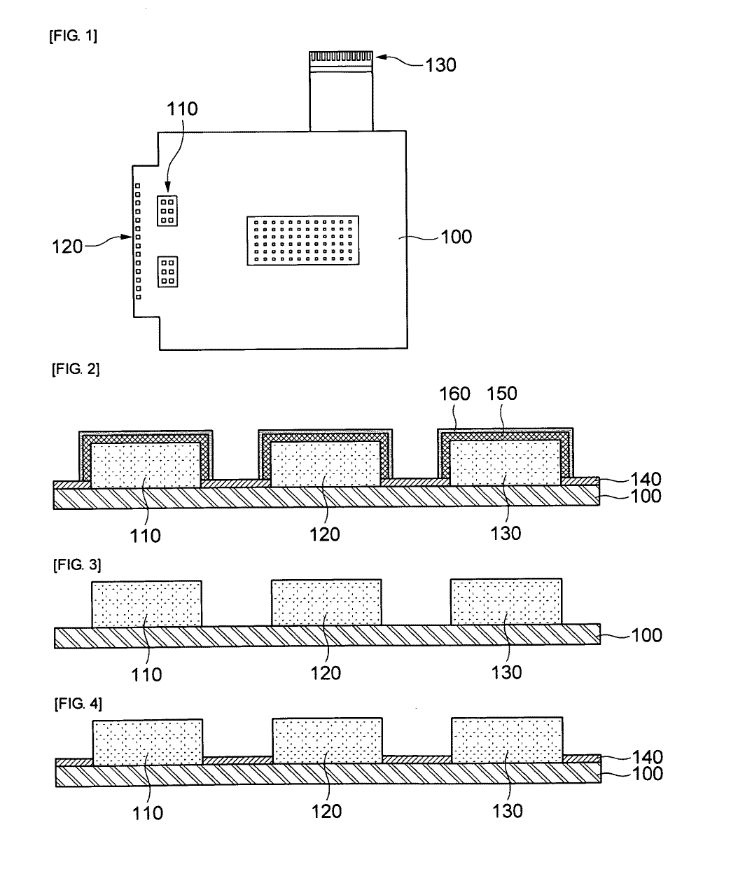

FIG. 1 is a plan view of a flexible printed circuit board in accordance with a second embodiment of the present invention.

FIG. 2 is a cross-sectional view of the flexible printed circuit board illustrated in FIG. 1.

Referring to FIGS. 1 and 2, the flexible printed circuit board includes a substrate 100 having a circuit pattern formed thereon, a pad unit 110 to mount an electronic component thereon while being electrically connected to the circuit pattern, and external connection units 120 and 130 electrically connected to an external device while being electrically connected to the circuit pattern.

Here, the external connection units 120 and 130 may include a terminal unit 120, which is electrically connected to the external device such as a liquid crystal panel by ACF bonding, and a connector unit 130, which is electrically connected to the external device by an attaching and detaching method.

A nickel plating layer 150 having a vertical growth structure is disposed on each of the pad unit 110 and the external connection units 120 and 130. The nickel plating layer 150 can give high solderability to the pad unit 110 and crack-resistance to the external connection units 120 and 130. That is, the nickel plating layer 150 can have both high solderability and crack-resistance.

The nickel plating layer 150 may be made of an electroless plating solution composition including a water-soluble compound, a reducing agent, a complexing agent and a vertical growth inducer. Here, the vertical growth inducer may be a compound having bismuth ions. Further, the electroless nickel plating solution composition may further include a vertical growth supplement consisting of one or two or more selected from a group consisting of thallium ions, iron ions and copper ions.

Specifically, based on the total weight of the electroless nickel plating solution composition, a composition range of the water-soluble nickel compound is 1.0 to 10.0 wt %, a composition range of the reducing agent is 1.0 to 10.0 wt %, a composition range of the complexing agent is 1.0 to 10.0 wt % and a composition range of the vertical growth inducer is 0.001 to 1.0 wt %. In addition, the electroless nickel plating solution composition may further include a sequestering agent having a composition range of 0.01 to 1.0 wt %, organic acid and alkali metal salt thereof having a composition range of 0.1 to 10.0 wt % and at least one or more carboxyl (—COOH), a stabilizer having a composition range of 0.0001 to 0.1 wt %, a surfactant having a composition range of 0.01 to 10.0 wt % and a monosaccharide having a composition range of 0.1 to 10.0 wt %.

Here, the nickel plating layer 150 may include nickel having a composition range of 90 to 94 wt % and phosphorus having a composition range of 6 to 10 wt %. At this time, in case that a composition of the phosphorus is less than 6 wt %, a problem in corrosiveness of the nickel plating layer 150 can be generated. On the other hand, in case that the composition of the phosphorus is more than 10 wt %, there is a problem of solderability deterioration.

Further, the nickel plating layer 150 may have a thickness range of 1 to 5 μm. Here, preferably, the nickel plating layer 150 may have a thickness range of 1.5 to 3.5 μm. However, a thickness of the nickel plating layer 150 is not limited in the embodiment of the present invention.

In addition, a gold plating layer 160 may be disposed on the nickel plating layer 150. The gold plating layer 160 improves reliability of the flexible printed circuit board by preventing oxidation of the nickel plating layer 150.

Further, the flexible printed circuit board may further include an insulating layer 140 which is disposed on the substrate 100 while exposing the pad unit 110 and the external connection units 120 and 130. The insulating layer 140 can play a role in protecting the circuit pattern formed on the substrate 100 during a plating process.

Therefore, the flexible printed circuit board in accordance with the embodiment of the present invention can secure reliability through a simple manufacturing process by including the nickel plating layer having a vertical growth structure, which can satisfy both solderability of the pad unit and crack-resistance of the external connection units.

FIGS. 3 to 6 are cross-sectional views illustrating a manufacturing process of a flexible printed circuit board in accordance with a third embodiment of the present invention.

Referring to FIG. 3, in order to manufacture the flexible printed circuit board, first, a circuit pattern, a pad unit 110 and external connection units 120 and 130 are formed on a substrate 100. Here, the external connection units 120 and 130 may be, for example, a terminal unit 120 and a connector 130. The circuit pattern, the pad unit 110 and the external connection units 120 and 130 can be formed by using a general photolithography method.

Referring to FIG. 4, an insulating layer 140 is formed on the substrate 100 while exposing the pad unit 110 and the external connection units 120 and 130. The insulating layer 140 plays a role of a resist to plating during the following plating process. The insulating layer 140 can be formed by punching and thermocompression bonding. However, a method of forming the insulating layer 140 is not limited in the embodiment of the present invention.

Referring to FIG. 5, a nickel plating layer 150 is formed by contacting and depositing the substrate 100 including the pad unit 110 and the external connection units 120 and 130 in an electroless nickel plating solution.

The electroless nickel plating solution composition may include a water-soluble nickel compound, a reducing agent, a complexing agent and a vertical growth inducer. Specifically, the electroless nickel plating solution composition may include 1.0 to 10.0 wt % of the water-soluble nickel compound, 1.0 to 10.0 wt % of the reducing agent, 1.0 to 10.0 wt % of the complexing agent, 0.01 to 1.0 wt % of a sequestering agent, 0.1 to 10.0 wt % of organic acid and alkali metal salt thereof, 0.0001 to 0.1 wt % of a stabilizer, 0.01 to 10.0 wt % of a surfactant, 0.1 to 10.0 wt % of a monosaccharide and 0.001 to 1.0 wt % of the vertical growth inducer, based on the total weight thereof.

In the present invention, pH of the plating solution may be 4 to 6, preferably, 4.5 to 5.0. Further, a temperature required for the plating process may be 70 to 95° C., preferably, 80 to 85° C.

The nickel plating layer 150 is formed in a vertical growth type nickel structure by the vertical growth inducer. At this time, in the nickel plating layer 150, nickel may be included in a composition range of 90 to 94 wt %, and phosphorus (P) may be included in a composition range of 6 to 10 wt %.

A thickness range of the nickel plating layer 150 may be 1 to 5 μm, preferably, 1.5 to 3.0 μm.

The plating process for forming the nickel plating layer 150 may be performed for 10 to 20 minutes.

Referring to FIG. 6, a gold plating layer 160 may be further formed on the substrate 100 including the nickel plating layer 150 by an immersion gold plating method.

A reaction principle for forming the gold plating layer 160 is as the following Equation 4.

2K[Au (CN)₂]+Ni⁰→2Au+K₂[Ni(CN)₄] [Equation 4]

As shown in Equation 4, when a nickel-plated surface is brought in contact with an aqueous solution including citric acid and potassium gold cyanide, the gold plating layer 160 can be formed by a dissolution reaction of nickel and a precipitation reaction of gold (Au), which are performed at the same time.

In addition, a pretreatment process may be further performed during the plating process in order to form the optimum vertical growth type nickel plating layer 150 before forming the nickel plating layer 150. That is, foreign materials on surfaces of the pad unit 110 and the external connection units 120 and 130 are removed by performing physical polishing, and organic materials are chemically removed. Further, an activation treatment can be performed by selectively treating a palladium (Pd) solution serving as a catalyst after etching a surface of a copper layer constituting the pad unit 110 and the external connection units 120 and 130 as much as approximately 1 μm by using sulfuric acid and an oxidizing agent.

Therefore, in the embodiment of the present invention, the flexible printed circuit board can be manufactured by a simple process by forming the electroless nickel plating layer having a vertical growth structure, which can satisfy plating characteristics respectively required for the pad unit and the external connection units.

Hereinafter, another flexible printed circuit board in accordance with the embodiment of the present invention will be described in detail with reference to the following experimental examples. However, the scope of the present invention is not limited thereto.

In the following experimental example, a flexible printed circuit board (size 400×505 mm, thickness 0.2±0.02 mm and copper layer thickness 10˜30 μm) having an insulating layer in a portion except a pad unit, a terminal unit and a connector unit, which are made of copper, a flexible printed circuit board (size 50 mm×80 mm, substrate thickness 0.2±0.02 mm and copper layer thickness 10˜30 μm) for measuring ball shear strength and an MIT coupon (circuit width 100 μm×interval 100 μm, size 10 mm×100 mm, copper layer thickness 12 μm, substrate 100 thickness 25 μm and material polyimide) for a bending test are degreased at a temperature of 50° C. for 3 minutes by using acid (sulfuric acid concentration 50˜100 g/L, YMT Co. product name SAC 161H). Then, in order to remove an oxide film and form a surface roughness of copper, after performing pickling and etching (sulfuric acid 30 g/L, sodium persulfate 100 g/L), cleaning is performed after treating palladium (Pd) ions (YMT Co. product name CF Activator) as a catalyst. After that, a vertical growth type electroless nickel plating process is performed on the copper layer, and then a gold plating layer is formed on a vertical growth type electroless nickel plating layer by depositing in an immersion gold plating solution (YMT Co. product name MIKO Auromerse II) using citric acid as a main material at a temperature of 85° C. for 6 minutes.

TABLE 1

| | | Composition No. | | | | | | | | | | | | | | | |
|---|---|---|---|---|---|---|---|---|---|---|---|---|---|---|---|---|---|
| Constitution | Component | 1 | 2 | 3 | 4 | 5 | 6 | 7 | 8 | 9 | 10 | 11 | 12 | 13 | 14 | 15 | Unit |
| Carboxyl- | Acetic acid | 20 | | | 20 | | | 20 | | | 20 | | | 20 | | | g/L |
| containing | Amino acetic | | 20 | | | 20 | | | 20 | | | 20 | | | 20 | | |
| organic acid | acid | | | | | | | | | | | | | | | | |
| | Formic acid | | | 20 | | | 20 | | | 20 | | | 20 | | | 20 | |
| Thio compound | Mercapto- | 1 | 1 | 1 | | | | | | | 1 | 1 | 1 | | | | m/L |
| | benzothiazole | | | | | | | | | | | | | | | | |
| | Methylthiourea | | | | 1 | 1 | 1 | | | | | | | | | | |
| | Thio diglycolic | | | | | | | 1 | 1 | 1 | | | | 1 | 1 | 1 | |
| | acid | | | | | | | | | | | | | | | | |
| Poly- | Polyoxyethylene | 3 | 3 | 3 | 3 | 3 | 3 | 3 | 3 | 3 | | | | | | | g/L |
| oxyethylene | lauryl ether | | | | | | | | | | | | | | | | |
| alkyl ether | Polyoxyethylene | | | | | | | | | | 3 | 3 | 3 | 3 | 3 | 3 | |
| surfactant | laurylamine | | | | | | | | | | | | | | | | |
| | ether | | | | | | | | | | | | | | | | |
| Mono- | Glucose | 10 | 10 | 10 | 10 | 10 | 10 | 10 | 10 | 10 | | | | | | | g/L |
| saccharide | Fructose | | | | | | | | | | 10 | 10 | 10 | | | | |
| compound | Galactose | | | 10 | | | | | | | | | | 10 | 10 | 10 | |
| Metal ion | Bismuth | 1 | 1 | 1 | 1 | 1 | 1 | 1 | 1 | 1 | 1 | 1 | 1 | 1 | 1 | 1 | m/L |
| Nickel | Nickel sulfate | 22.5 | 22.5 | 22.5 | 22.5 | 22.5 | 22.5 | 22.5 | 22.5 | 22.5 | 22.5 | 22.5 | 22.5 | 22.5 | 22.5 | 22.5 | g/L |
| compound | (6 hydrate) | | | | | | | | | | | | | | | | |
| Reducing agent | Sodium | 25 | 25 | 25 | 25 | 25 | 25 | 25 | 25 | 25 | 25 | 25 | 25 | 25 | 25 | 25 | g/L |
| | hyphophosphite | | | | | | | | | | | | | | | | |
| Complexing | Lactic acid | 20 | 20 | 20 | 20 | 20 | 20 | 20 | 20 | 20 | 20 | 20 | 20 | 20 | 20 | 20 | g/L |
| agent | | | | | | | | | | | | | | | | | |
| Chelating agent | Nitriloacetic acid | 5 | 5 | 5 | 5 | 5 | 5 | 5 | 5 | 5 | 5 | 5 | 5 | 5 | 5 | 5 | g/L |

### EXPERIMENTAL EXAMPLE

After manufacturing a vertical growth type electroless nickel plating solution having a composition of Table 1, as described above, a palladium (Pd) catalyst-treated flexible printed circuit board is cleaned and then deposited in a 5 wt % sulfuric solution for 1 minute and cleaned. After that, electroless nickel plating is performed by using the vertical growth type electroless nickel plating solution. At this time, the plating is performed under the conditions that a temperature of the electroless nickel plating solution is 82° C. and pH thereof is 4.5, a plating time is 15 minutes and a liquid circulation amount is 3 cycles/time.

An electroless nickel plating layer is formed by the above-described method and conditions, cleaned and dried at a temperature of 80° C. for 15 minutes. After that, a plating thickness, solderability, flexibility, adhesive force, porosity and heat-resistance of the electroless nickel plating layer are measured.

<Plating Thickness Measurement>

Used measurement equipment is as follows, and measurement results are shown in Table 2.

Measurement Equipment

Manufacturer: Oxford Instrument

Model: CMI 900

Measurement pad size: 1×1 mm

<Solderability Measurement>

Measurement results of solderability, which are obtained by performing a solder ball shear test and a solder spread test, are shown in Table 3.

1) Solder Ball Shear Test

Conditions

Bond tester: DAGE 4000

Location : 100 μm

Shear speed: 700 μm/sec.

Load : 5 kgf

Ball size: 0.4 mmφ (D (Alpha Metal Co.)

Ball material: Sn/Ag/Cu (96.5/310.5)wt %

Flux (RMA type): WF-6063M (Senju Co.)

Reflow machine: Heller (1809 UL)

Reflow condition: 245° C. (peak temperature)

Evaluation Method:

As it is to measure connection strength between a soldering pad unit and a solder ball, when the ball shear test is performed under the above conditions by fixing a sample with a solder bump to a table and setting predetermined load and shear height, a stylus pushes the bump and thus breaking occurs. At that time, values are measured.

Evaluation References:

If ball shear strength is more than 600 gf, it is considered that there is no abnormality.

2) Solder Paste Spread Test

Conditions:

Solder paste: Sn/Ag/Cu (96.5/310.5)wt % (Senju Co.)

Reflow machine: Heller (1809 UL)

Reflow condition: 245° C. (peak temperature)

Evaluation Method:

Solder spread is measured in a soldering pad unit by passing the soldering pad unit through the reflow machine after coating solder paste on the soldering pad unit.

Evaluation References:

If more than 95% of the soldering pad unit is spread after reflow, it is considered that there is no abnormality in solderability.

<Flexibility Measurement>

The number of disconnections due to cracks of a circuit is measured, and measurement results are shown in Table 4 by performing a bending test under the following measurement conditions.

Measurement Conditions

Load: 500 g

Bend radius: 0.38 mm

Speed: 175 times/minute

Bend angle: total 270° (horizontal 135°)

Measurement mode: disconnection evaluation

Measurement Sample

Thickness: polyimide 25 cm, copper (electro copper foil) 12 μm

Measurement Equipment

Manufacturer: TOYOSEIKI

Model: MIT-DA

<Adhesive Force Measurement>

The adhesion or lifting of the plating layer is checked by removing a 3M #810 tape in a vertical direction after pressing the tape to a surface of plating with finger pressure, and checking results are shown in Table 5.

<Porosity Measurement>

The generation of pores due to corrosion of nickel and gold plating structure is checked by a microscope after depositing the plated flexible printed circuit board in a 12 wt % nitric acid solution for 15 minutes, and checking results are shown in Table 5.

<Heat-Resistance Measurement>

The surface oxidation or corrosion of nickel-gold plating due to heat is checked by an adhesion test using a tape after passing the nickel-gold plating three times using a reflow machine, and checking results are shown in Table 5.

TABLE 2
Plating thickness measurement results

| | | No. | | | | | | | | | | | | | | |
|---|---|---|---|---|---|---|---|---|---|---|---|---|---|---|---|---|
| Classification | | 1 | 2 | 3 | 4 | 5 | 6 | 7 | 8 | 9 | 10 | 11 | 12 | 13 | 14 | 15 |
| Plating | Nickel | 2.23 | 2.31 | 2.27 | 2.42 | 2.25 | 2.18 | 2.33 | 2.27 | 2.20 | 2.30 | 2.26 | 2.19 | 2.21 | 2.40 | 2.35 |
| thickness | Gold | 0.05 | 0.05 | 0.06 | 0.05 | 0.05 | 0.04 | 0.06 | 0.06 | 0.05 | 0.06 | 0.05 | 0.05 | 0.05 | 0.05 | 0.06 |
| (μm) | | | | | | | | | | | | | | | | |

TABLE 3
Solderability measurement results (solder ball shear strength)

| | No. | | | | | | | | | | | | | | |
|---|---|---|---|---|---|---|---|---|---|---|---|---|---|---|---|
| Classification | 1 | 2 | 3 | 4 | 5 | 6 | 7 | 8 | 9 | 10 | 11 | 12 | 13 | 14 | 15 |
| Φ0.4 mm | 766.5 | 845.1 | 824.3 | 773.9 | 870.0 | 773.3 | 783.2 | 772.4 | 774.9 | 775.1 | 770.8 | 769.6 | 836.1 | 789.5 | 818.3 |
| solder ball | | | | | | | | | | | | | | | |
| shear strength | | | | | | | | | | | | | | | |
| (gf) | | | | | | | | | | | | | | | |

TABLE 4
Flexibility measurement results

| | No. | | | | | | | | | | | | | | |
|---|---|---|---|---|---|---|---|---|---|---|---|---|---|---|---|
| Classification | 1 | 2 | 3 | 4 | 5 | 6 | 7 | 8 | 9 | 10 | 11 | 12 | 13 | 14 | 15 |
| Flexibility | 398 | 421 | 402 | 385 | 433 | 410 | 408 | 399 | 425 | 407 | 411 | 396 | 394 | 438 | 423 |
| (number to crack) | | | | | | | | | | | | | | | |

TABLE 5
Characteristics evaluation results

| Test item | | Standard | Test content | Result |
|---|---|---|---|---|
| Plating thickness | | Nickel: 1~3 um | Measurement using an X-ray thickness | ◯ |
| | | Gold: more than 0.03 um | measuring instrument(CMI Co. CMI 900) | |
| Solderability | Solder | More than 95% | Reflow after coating Pb-free solder | ◯ |
| | ball | | paste(Senju Co.) | |
| | spread | | | |
| | Solder | More than 600 gf | Ball shear valve measurement using | ◯ |
| | ball | | Dage-4000 equipment | |
| | shear | | | |
| | strength | | | |

| | | | |
|---|---|---|---|
| Flexibility | More than 20 times | Flexibility test using MIT equipment(PI | ◯ |
| | | 25 μm, Cu 12 μm) | |
| Plating adhesive force | No separation of a plating layer | Test using a 3M #810 tape | ◯ |
| | during an adhesive force test | | |
| | using a tape | | |
| Porosity | No oxidation, corrosion and pore | Observation by cleaning and drying after | ◯ |
| | of a plating layer | depositing a plated printed circuit board | |
| | | in a 12% nitric acid solution | |
| Heat-resistance | No discoloration and separation of | Tape peel test after continuously | ◯ |
| | a plating layer during a tape peel | passing a tape through IR-reflow three | |
| | test | times | |
| | | Speed: 240 rpm | |
| | | Temperature: referring to reflow profile | |

In Table 5, ‘◯’ means that it satisfies a standard as a result of test.

According to results of Tables 2 to 5, it is checked that the vertical growth type nickel plating layer and the gold plating layer in accordance with the embodiment of the present invention satisfy both solderability and crack-resistance.

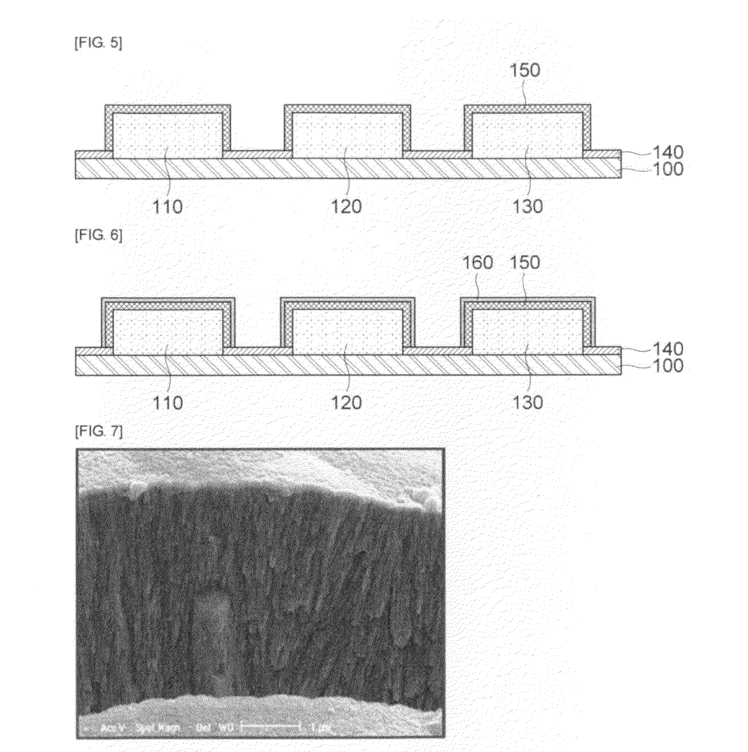

FIG. 7 is a photograph of a fracture cross-section of an electroless nickel plating layer having a vertical growth structure in accordance with an embodiment of the present invention.

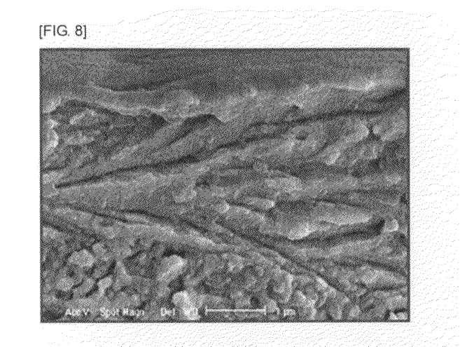

FIG. 8 is a photograph of a fracture cross section of an electroless nickel plating layer having a vertical growth structure in accordance with a comparative example of the present invention.

As shown in FIGS. 7 and 8, it is checked that the electroless nickel plating layer has a horizontal structure, unlike that it is checked that the electroless nickel plating layer has a vertical growth structure in case of having a vertical growth inducer.

Therefore, the electroless nickel plating solution composition in accordance with the present invention can form a nickel plating layer having all of solderability, flexibility and crack-resistance by including the vertical growth inducer.

Further, plating characteristics respectively required for the pad unit and the external connection units of the flexible printed circuit board can be satisfied by using the electroless nickel plating solution in accordance with the present invention.

Further, a double plating process of general electroless nickel plating and direct gold plating, which is performed during manufacture of a conventional flexible printed circuit board, can be replaced with a single plating process, thereby contributing to simplification of processes, improvement of productivity and remarkable reduction of cost.

Further, although it is explained that the electroless nickel plating solution composition in accordance with the embodiment of the present invention is used in manufacturing the flexible printed circuit board, it is not limited thereto, and the electroless nickel plating solution composition can be applied to all types of printed circuit boards.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An electroless nickel plating solution composition comprising a water-soluble nickel compound, a reducing agent, a complexing agent and a vertical growth inducer.

2. The electroless nickel plating solution composition according to claim 1, wherein the vertical growth inducer includes a compound having bismuth ions.

3. The electroless nickel plating solution composition according to claim 1, wherein a composition range of the vertical growth inducer is 0.001 to 1 wt % based on the total content of the electroless nickel plating solution composition.

4. The electroless nickel plating solution composition according to claim 1, further comprising a vertical growth supplement.

5. The electroless nickel plating solution composition according to claim 4, wherein the vertical growth supplement includes at least one or two or more selected from a group consisting of thallium ions, iron ions and copper ions.

6. The electroless nickel plating solution composition according to claim 1, wherein the water-soluble nickel compound includes at least one of nickel sulfate and nickel chloride.

7. The electroless nickel plating solution composition according to claim 1, wherein a composition range of the water-soluble nickel compound is 1 to 10 wt % based on the total electroless nickel plating solution composition.

8. The electroless nickel plating solution composition according to claim 1, wherein the reducing agent includes at least one selected from a group consisting of hypophosphorous acid, potassium hypophosphite, hydrazine and sodium hypophosphite.

9. The electroless nickel plating solution composition according to claim 1, wherein a composition range of the reducing agent is 1 to 10 wt % based on the total electroless nickel plating solution composition.

10. The electroless nickel plating solution composition according to claim 1, wherein the complexing agent includes at least one or two or more selected from a group consisting of lactic acid, glycolic acid and a malic acid.

11. The electroless nickel plating solution composition according to claim 1, wherein a composition range of the complexing agent is 1 to 10 wt % based on the total electroless nickel plating solution composition.

12. The electroless nickel plating solution composition according to claim 1, further comprising at least one among a sequestering agent, organic acid and alkali metal salt thereof, a monosaccharide, a surfactant and a stabilizer.

13. The electroless nickel plating solution composition according to claim 12, wherein the sequestering agent includes at least one or two or more selected from a group consisting of polycarboxylic acid derivatives, amino acetic acid derivatives and nitrilo-triacetic acid derivatives.

14. The electroless nickel plating solution composition according to claim 12, wherein a composition range of the sequestering agent is 0.01 to 1 wt % based on the total electroless nickel plating solution composition.

15. The electroless nickel plating solution composition according to claim 12, wherein the organic acid and the alkali metal salt thereof include at least one or two or more selected from a group consisting of acetic acid, sodium acetate, propionic acid, sodium propionate, formic acid, sodium formate, potassium formate, adipic acid, sodium adipate, succinic acid, sodium succinate and so on.

16. The electroless nickel plating solution composition according to claim 12, wherein a composition range of the organic acid and the alkali metal salt thereof is 0.1 to 10 wt % based on the total electroless nickel plating solution composition.

17. The electroless nickel plating solution composition according to claim 12, wherein the monosaccharide includes at least one or two or more selected from a group consisting of glucose, fructose and galactose.

18. The electroless nickel plating solution composition according to claim 12, wherein a composition range of the monosaccharide is 0.1 to 10 wt % based on the total electroless nickel plating solution composition.

19. The electroless nickel plating solution composition according to claim 12, wherein the surfactant is a polyoxyethylene alkyl ether derivative.

20. The electroless nickel plating solution composition according to claim 12, wherein the surfactant includes at least one or two or more selected from a group consisting of polyoxyethylene lauryl ether, polyoxyethylene oleyl ether, polyoxyethylene cetyl ether, polyoxyethylene octyl ether, polyoxyethylene tridecyl ether, polyoxyethylene laurylamine ether and polyoxyethylene stearylamine ether.

21. The electroless nickel plating solution composition according to claim 12, wherein a composition range of the surfactant is 0.01 to 10 wt % based on the total electroless nickel plating solution composition.

22. The electroless nickel plating solution composition according to claim 12, wherein the stabilizer is a thio compound.

23. The electroless nickel plating solution composition according to claim 12, wherein the stabilizer includes at least one or two or more selected from a group consisting of thiourea, alkyl thiourea, a mercapto compound, a tyazole compound, sodium thiosulfate, sodium thiocyanate, potassium thiocyanate, thio glycolic acid and thio diglycolic acid.

24. The electroless nickel plating solution composition according to claim 12, wherein a composition range of the stabilizer is 0.0001 to 0.1 wt % based on the total electroless nickel plating solution composition.

25. The electroless nickel plating solution composition according to claim 1, wherein a pH range of the electroless nickel plating solution composition is 4 to 6.

26. A flexible printed circuit board comprising:
a substrate having a circuit pattern formed thereon;
a pad unit to mount an electronic component thereon while being electrically connected to the circuit pattern;
external connection units electrically connected to an external device while being electrically connected to the circuit pattern; and
a nickel plating layer having a vertical growth structure and formed on the pad unit with an electroless nickel plating solution composition including a water-soluble nickel compound, a reducing agent, a complexing agent and a vertical growth inducer.

27. The flexible printed circuit board according to claim 26, wherein the nickel plating layer is further formed on the external connection units.

28. The flexible printed circuit board according to claim 26, wherein the external connection units include at least one of a terminal unit and a connector unit.

29. The flexible printed circuit board according to claim 26, wherein the nickel plating layer includes nickel having a composition range of 90 to 94 wt % and phosphorus having a composition range of 6 to 10 wt %.

30. The flexible printed circuit board according to claim 26, wherein the nickel plating layer has a thickness range of 1 to 5 μm.

31. The flexible printed circuit board according to claim 26, further comprising a gold plating layer disposed on the nickel plating layer.

32. The flexible printed circuit board according to claim 31, wherein the gold plating layer has a thickness range of 0.05 to 0.1 μm.

33. The flexible printed circuit board according to claim 26, wherein the electroless nickel plating solution composition further includes organic acid and alkali metal salt thereof, a stabilizer, a surfactant, a monosaccharide and a sequestering agent.

34. The flexible printed circuit board according to claim 26, wherein the vertical growth inducer includes a compound having bismuth ions.

35. The flexible printed circuit board according to claim 26, further comprising a vertical growth supplement consisting of at least one or two or more selected from a group consisting of thallium ions, iron ions and copper ions.

36. The flexible printed circuit board according to claim 26, further comprising an insulating layer disposed on the substrate while exposing the pad unit and the external connection units.

37. A manufacturing method of a flexible printed circuit board comprising the steps of:
preparing a substrate including a circuit pattern, a pad unit electrically connected to the circuit pattern and external connection units electrically connected to an external device while being electrically connected to the circuit pattern; and
forming a nickel plating layer on the pad unit with an electroless nickel plating solution composition including a water-soluble nickel compound, a reducing agent, a complexing agent and a vertical growth inducer.

38. The method according to claim 37, wherein the nickel plating layer is further formed on the external connection units.

39. The method according to claim 37, wherein a gold plating layer is further formed on the nickel plating layer.

40. The method according to claim 37, wherein in the step of forming the nickel plating layer, the electroless nickel plating solution composition has a temperature range of 70 to 90° C.

41. The method according to claim 37, wherein in the step of forming the nickel plating layer, a pH range of the electroless nickel plating solution composition is 4 to 6.

42. The method according to claim 37, wherein a composition range of the water-soluble nickel compound is 1.0 to 10.0 wt %, a composition range of the reducing agent is 1.0 to 10.0 wt %, a composition range of the complexing agent is 1.0 to 10.0 wt % and a composition range of the vertical growth inducer is 0.001 to 0.1 wt %, based on the total weight of the electroless nickel plating solution composition.

43. The method according to claim 37, wherein the electroless nickel plating solution composition further includes 0.1 to 10.0 wt % of organic acid and alkali metal salt thereof, 0.0001 to 0.1 wt % of a stabilizer, 0.01 to 10.0 wt % of a surfactant, 0.1 to 10.0 wt % of a monosaccharide and 0.01 to 1.0 wt % of a sequestering agent, based on the total weight thereof.
